(19) United States
(12) Patent Application Publication
(10) Pub. No.: US 2022/0244872 A1
(43) Pub. Date: Aug. 4, 2022

(54) STORAGE METHOD, DATA PROCESSING METHOD, DEVICE AND APPARATUS BASED ON NON-VOLATILE MEMORY

(71) Applicant: INSTITUTE OF MICROELECTRONICS OF THE CHINESE ACADEMY OF SCIENCES, BEIJING (CN)

(72) Inventors: Feng ZHANG, BEIJING (CN); Qiang HUO, BEIJING (CN); Zhisheng CHEN, BEIJING (CN); Qirui REN, BEIJING (CN)

(73) Assignee: INSTITUTE OF MICROELECTRONICS OF THE CHINESE ACADEMY OF SCIENCES, BEIJING (CN)

(21) Appl. No.: 17/595,847

(22) PCT Filed: Apr. 22, 2021
(86) PCT No.: PCT/CN2021/089040

§ 371 Date: Nov. 26, 2021

(30) Foreign Application Priority Data
May 28, 2020 (CN) 202010468344.0

(51) Int. Cl. G06F 3/06; G11C 13/00

(52) U.S. Cl. CPC G06F 3/0634; G06F 3/061; G11C 13/0004; G11C 13/0069; G06F 3/0673

(57) ABSTRACT

The present disclosure discloses a storage method, a data processing method, a device and an apparatus based on a non-volatile memory, the method comprising: acquiring a weight value that needs to be stored in the non-volatile memory; determining a conductivity value corresponding to the weight value according to a first conversion method if the non-volatile memory is a high-resistance storage device; determining a conductivity value corresponding to the weight value according to a second conversion method which is different from the first conversion method if the non-volatile memory is a low-resistance memory device; and setting the non-volatile memory according to the conductivity value to store the weight value. The non-volatile memory and the data processing method, the device, and the apparatus provided by the present disclosure solve the problem of insufficient accuracy in weight values in existing non-volatile memories, realizing the technical effect of improving storage accuracy and data processing accuracy.

### CROSS-REFERENCE OF RELATED ART

The present application claims priority of China's patent application No. 202010468344.0 entitled “Storage method, data processing method, device and apparatus based on non-volatile memory”, all contents of which are incorporated herein by reference here.

### TECHNICAL FIELD

The present disclosure relates to the field of electronic technology, and more particularly to a storage method, a data processing method, a device and an apparatus based on a non-volatile memory.

### BACKGROUND OF THE INVENTION

A non-volatile memory, such as a resistance random access memory (RRAM), a phase change memory (PCM) or the like, is widely used in a neural network accelerator based on In-memory computing (IMC). A non-volatile memory in a neural network accelerator is often used for a multiply-accumulative operation with weight values. At this time, the storage of a weight value in the non-volatile memory is realized by converting the weight value into a suitable conductivity value.

However, weight values of a neural network stored in non-volatile memory units are not able to be accurately expressed due to the limited conductivity switching ratio of the device configured with the non-volatile memory units, so the storage accuracy is not sufficient, resulting in a technical problem of insufficient data processing accuracy.

### SUMMARY OF THE INVENTION

In view of the above problem, a storage method, a data processing method, a device and an apparatus based on a non-volatile memory are provided to overcome or at least partially address the above problem.

In a first aspect, the present disclosure provides a storage method based on a non-volatile memory, comprising: acquiring a weight value that needs to be stored in the non-volatile memory; determining a conductivity value corresponding to the weight value according to a first conversion method if the non-volatile memory is a high-resistance storage device; determining a conductivity value corresponding to the weight value according to a second conversion method which is different from the first conversion method if the non-volatile memory is a low-resistance memory device; and setting the non-volatile memory according to the conductivity value to store the weight value.

In some embodiments, said determining a conductivity value corresponding to the weight value according to a first conversion method comprising: determining a conductivity value corresponding to the weight value according to the following formula

$$G = \{ \begin{matrix}{g}_{min} , & n = 0 \\ {g}_{min} * n * \frac{w}{{K}^{m} - 1} , & n = 1 , … , {K}^{m} - 1\end{matrix} ,$$

where G is the conductivity value, n is the weight value, and gₘᵢₙ is a lowest conductivity value corresponding to a preset minimum weight value, K is the carry number of the carry system used for the weight value, and m is the number of digits of K carry system used for the weight value, and w is a conductivity switching ratio of the non-volatile memory.

In some embodiments, said determining a conductivity value corresponding to the weight values according to a second conversion method comprising determining a conductivity value corresponding to the weight value according to the following formula

$$G = {g}_{min} + {g}_{min} * n * \frac{w - 1}{{K}^{m} - 1} , n = 0 , . . . , {K}^{m} - 1 ,$$

where G is the conductivity value, n is the weight value, and gₘᵢₙ is a lowest conductivity value corresponding to a preset minimum weight value, K is the carry number of the carry system used for the weight value, and m is the number of digits of K carry system used for the weight value, and w is a conductivity switching ratio of the non-volatile memory.

In some embodiments, the carry system used for the weight value is a binary system.

In some embodiments, the non-volatile memory is a non-volatile memory in a neural network accelerator, and the weight value is a weight value of a neural network.

In a second aspect, the present disclosure provides a data processing method based on a non-volatile memory array, comprising: receiving a group of data values in the form of voltage input into the non-volatile memory array; processing the group of data values based on weight values stored in non-volatile memories of the non-volatile memory array; outputting a result of a multiply-accumulation operation performed on the group of data values and the weight values in the non-volatile memories; wherein a weight value in each of the non-volatile memories is stored according to the method of the first aspect.

In a third aspect, a storage device based on a non-volatile memory comprising: an acquisition module for acquiring a weight value that needs to be stored in the non-volatile memory; a high-resistance conversion module configured for determining a conductivity value corresponding to the weight value according to the first conversion method if the non-volatile memory is a high-resistance storage device; a low-resistance conversion module configured for determining a conductivity value corresponding to the weight value according to the second conversion method which is different from the first conversion method if the non-volatile memory is a low-resistance memory device; and a storage module configured for setting the non-volatile memory according to the conductivity value to store the weight value.

In a fourth aspect, a non-volatile memory array comprising: an input configured for receiving a group of data values in the form of voltage input into the non-volatile memory array; an array module configured for processing the group of data values based on weight values stored in non-volatile memories of the non-volatile memory array, wherein a weight value in each of the non-volatile memories is stored according to the method of the first aspect; an output configured for outputting a result of a multiply-accumulation operation performed on the group of data values and the weight values in the non-volatile memories.

In a fifth aspect, a neural network accelerator is provided, comprising a non-volatile memory array according to the fourth aspect.

In a sixth aspect, an electronic apparatus is provided, comprising a neural network accelerator according to the fifth aspect.

With the storage method, the data processing method, the device and the apparatus based on a non-volatile memory according to the present disclosure, it is determined whether the non-volatile memory is a high-resistance memory device or a low-resistance memory device, and then different weight value-conductivity conversion methods are selected based on the type of the non-volatile memory, so that converted conductivity values are more adaptable, and more accurate to express corresponding weight values, thereby increasing the accuracy of storage and the accuracy of data processing.

The above is merely a summary of technical solutions of the present disclosure, in order to understand technical means of the present disclosure to implement the invention in accordance with the contents of the description, and in order to make the above and other objects, features, and advantages of the present disclosure more clear and readily understandable, the specific embodiments of the invention will be illustrated hereinafter.

### BRIEF DESCRIPTION OF THE DRAWINGS

Various other advantages and benefits will become apparent to those of ordinary skill in the art by reading a detailed description of preferred embodiments. The drawings are only used to illustrate the preferred embodiments, rather than limiting the present disclosure. Moreover, throughout the drawings, the same reference numerals are used for the same components. In the drawings:

FIG. 1 is a flow chart of a storage method based on a non-volatile memory in accordance with an embodiment of the present disclosure;

FIG. 2 is a flow chart of a data processing method based on a non-volatile memory in accordance with an embodiment of the present disclosure;

FIG. 3 is a schematic diagram of a non-volatile memory array in accordance with an embodiment of the present disclosure; and

FIG. 4 is a schematic structural diagram of a storage device based on a non-volatile memory in accordance with an embodiment of the present disclosure.

### DETAILED DESCRIPTION OF THE INVENTION

Exemplary embodiments of the present disclosure will be described in more details below with reference to the accompanying drawings. Although the exemplary embodiments of the present disclosure are shown in the drawings, it should be understood that the present disclosure can be implemented in various forms and should not be restricted by embodiments described herein. Instead, the embodiments are provided to more thoroughly understand the present disclosure, and communicate the scope of the disclosure more completely to those skilled in the art.

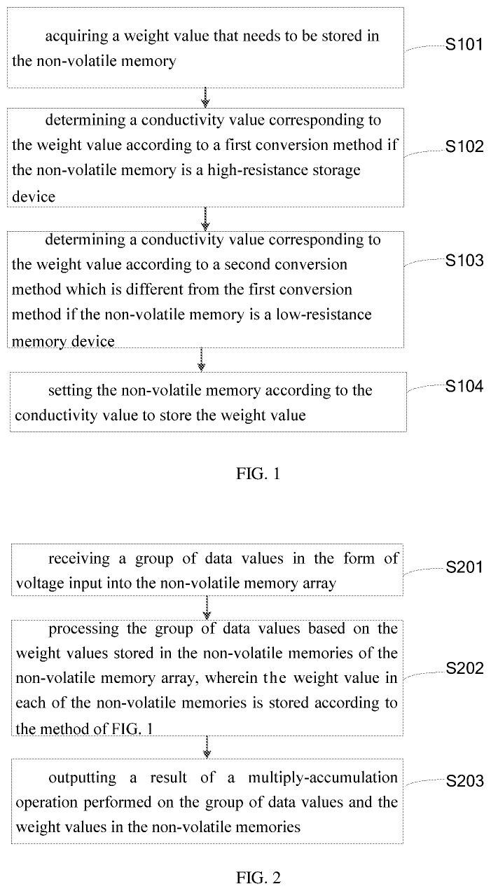

According to one aspect of the present disclosure, a storage method based on a non-volatile memory is provided, as shown in FIG. 1, comprising:

Step S101, acquiring a weight value that needs to be stored in the non-volatile memory;

Step S102, if the non-volatile memory is a high-resistance memory device, determining a conductivity value corresponding to the weight value according to a first conversion method;

Step S103, if the non-volatile memory is a low-resistance memory device, determining a conductivity value corresponding to the weight value according to a second conversion method which is different from the first conversion method; and

Step S104, setting the non-volatile memory according to the conductivity value to store the weight value.

In some embodiments, the non-volatile memory of the present embodiment may be a memory in a neural network accelerator, and the weight values to be stored are weight values of a neural network. Of course, the non-volatile memory can also be used in other chips that require computation or storage functions, and the weight values to be stored can also be set according to the specific requirements of the chip, which is not limited herein.

The non-volatile memory can be a resistive random access memory or a phase change memory, or the like, which is not limited herein. The non-volatile memory can be a memory device integrated into a chip, or a stand-alone memory device, which is not limited herein.

In some embodiments, the method provided in this embodiment can be applied to a separate computing device, or a chip, the chip may be a chip integrated with the memory device, or a separate computing chip, which is not limited herein.

The specific implementation steps of the storage method based on a non-volatile memory provided by the present embodiment will be described in detail below with reference to FIG. 1.

The step S101 is performed for acquiring a weight value that needs to be stored in the non-volatile memory.

The weight values are usually set in advance, and specifically they can be pre-calculated based on an algorithm corresponding to the scenario to be applied, or be set artificially based on experiences, or be obtained by performing analysis and statistics on data. The weight values may be expressed as numbers of any carry system, for example, may be binary numbers, or octal numbers, which is not limited herein. The number of the digits of the carry system used for the weight values can be set based on the scale of the amount of data to be calculated.

The type of the non-volatile memory is determined: if it is a high-resistance memory device, Step S102 is performed to determine a conductivity value corresponding to the weight value according to the first conversion method; if it is a low-resistance memory device, then Step S103 is performed to determine a conductivity value corresponding to the weight value according to the second conversion method, which is different from the first conversion method.

In some embodiments, the type of the resistance state of a non-volatile memory may be determined according to a pre-stored type data, or may be determined based on a real-time detection or calculation, which is not limited herein. Since the weight value is relatively high for a high-resistance state and relatively low for a low resistance state, for non-volatile memories of different types, different conversion methods are used, so that the converted conductivity values are more adaptive and represent weight values more accurately.

In some embodiments, if a non-volatile memory has a high-resistance state, a conductivity value corresponding to a weight value is determined according to the following formula

$$G = \{ \begin{matrix}{g}_{min} , n = 0 \\ {g}_{min} * n * \frac{w}{{K}^{m} - 1} , n = 1 , . . . , {K}^{m} - 1\end{matrix} ,$$

where G is the conductivity value, n is the weight value, and gₘᵢₙ is a lowest conductivity value corresponding to a preset minimum weight value, and K is a carry number of the carry system used for the weight value, and m is the number of digits of K carry system used for the weight value, and w is a conductivity switching ratio of the non-volatile memory.

Among them, gₘᵢₙ may be the lowest conductivity value corresponding to the minimum weight value preset artificially, or it may be a typical default value obtained based on experiences. K is the carry number of the carry system used for the weight value. In some embodiments, in order to reduce complexity in computation, the weight value is represented as a binary number, that is, K=2, and there are 2^{m} different conductive states in succession. Then, the following conductivity value formula according to the first conversion method is:

$$G = \{ \begin{matrix}{g}_{min} , n = 0 \\ {g}_{min} * n * \frac{w}{{2}^{m} - 1} , n = 1 , . . . , {2}^{m} - 1\end{matrix} ,$$

where m is the number of digits of K carry system set in advance, which specifically can be set according to the amount of data to be stored or processed. For example, the number m of digits of a binary number 0100101 is 7 (7 bit). w is a conductivity switching ratio of the non-volatile memory, also referred to as a window size of the device, and specifically, it can be obtained according to parameter values of the device, or be measured, which is not limited herein.

In some embodiments, if the non-volatile memory has a low-resistance state, then a conductivity value corresponding to a weight value is determined according to the following formula:

$$G = {g}_{min} + {{g}_{min}}^{*} {n}^{*} \frac{w - 1}{{K}^{m} - 1} , n = 0 , . . . , {K}^{m} - 1 ,$$

where G is the conductivity value; n is the weight value, and gₘᵢₙ is a lowest conductivity value corresponding to a preset minimum weight value; K is the carry number of the carry system used for the weight value, and m is the number of digits of K carry system used for the weight value, and w is a conductivity switching ratio of the non-volatile memory.

Among them, gₘᵢₙ, K, m and w are obtained as described above. In some embodiments, in order to reduce complexity in computation, the weight value is represented as a binary number, that is, K=2, and there is 2^{m} different conductive states in succession. Then, the following conductivity value formula corresponding to the second conversion method is:

$$G = {g}_{min} + {{g}_{min}}^{*} {n}^{*} \frac{w - 1}{{2}^{m} - 1} , n = 0 , . . . , {2}^{{m}_{-}} 1 .$$

The inventors of the present application have tested the conductivity values converted by the method according to the present embodiment when the non-volatile memory is high-resistant and low-resistant, respectively. As shown in the tables below, Table 1 is a conversion table assuming that K=2, m=3, w=70, gₘᵢₙ=0.1 ns, and the non-volatile memory is high-resistant, and Table 2 is a conversion table assuming that K=2, m=3, w=7, gₘᵢₙ=0.1 ns, and the non-volatile memory is low-resistant.

TABLE 1

| | | |
|---|---|---|
| | Conductivity Values | Conductivity Values |
| Weight | determined by the first | determined by the second |
| values | conversion method | conversion method |

| | | | | |
|---|---|---|---|---|
| 0 | 0.1 | nS | 0.1 | nS |
| 1 | 1 | nS | 1.09 | nS |
| 2 | 2 | nS | 2.07 | nS |
| 3 | 3 | nS | 3.05 | nS |
| 4 | 4 | nS | 4.04 | nS |
| 5 | 5 | nS | 5.03 | nS |
| 6 | 6 | nS | 6.01 | nS |
| 7 | 7 | nS | 7 | nS |

TABLE 2

| | | |
|---|---|---|
| | Conductivity Values | Conductivity Values |
| Weight | determined by the first | determined by the second |
| values | conversion method | conversion method |

| | | | | |
|---|---|---|---|---|
| 0 | 0.1 | nS | 0.1 | nS |
| 1 | 0.1 | nS | 0.186 | nS |
| 2 | 0.2 | nS | 0.271 | nS |
| 3 | 0.3 | nS | 0.357 | nS |
| 4 | 0.4 | nS | 0.443 | nS |
| 5 | 0.5 | nS | 0.529 | nS |
| 6 | 0.6 | nS | 0.614 | nS |
| 7 | 0.7 | nS | 0.7 | nS |

Thus, it can be seen that when the non-volatile memory is high-resistant, among the conductivity values calculated according to the formula

$$G = \{ \begin{matrix}{g}_{min} , n = 0 & \\ {g}_{min} * n * \frac{w}{{K}^{m} - 1} , n = 1 , . . . , {K}^{m} - 1 & \end{matrix}$$

corresponding to the first conversion method, except that the weight value 0 cannot be accurately represented by a conductivity value of the device, other weight values are all accurately converted, thereby realizing precise correspondence in mathematics; meanwhile, among the conductivity values calculated according to the formula

$$G = {g}_{min} + {g}_{min} * n * \frac{w - 1}{{K}^{m} - 1} , n = 0 , . . . , {K}^{m} - 1 , n = 0 , . . . , 2 \hat{} m - 1$$

corresponding to the second conversion method, all of the weight values 0˜7 cannot be accurately converted into conductivity values of the device.

When the non-volatile memory is low-resistant, among the conductivity values calculated according to the formula

$$G = \{ \begin{matrix}{g}_{min} , n = 0 & \\ {g}_{min} * n * \frac{w}{{K}^{m} - 1} , n = 1 , . . . , {K}^{m} - 1 & \end{matrix}$$

corresponding to the first conversion method, the conductivity values of the device corresponding to the weight values 0 and 1 are heavily overlapped. Thus, it can be seen that this conversion method is not feasible for a low-resistance state due to a very small conductivity switching ratio; meanwhile, among the conductivity values calculated according to the formula

$$G = {g}_{min} + {g}_{min} * n * \frac{w - 1}{{K}^{m} - 1} , n = 0 , . . . , {K}^{m} - 1 , n = 0 , . . . , 2 \hat{} m - 1$$

corresponding to the second conversion method, although the weight values 0˜7 cannot be exactly converted into conductivity values, they maintain mathematical correspondences to some extent.

Therefore, a conductivity value converted by this embodiment is more adaptable, and more accurate to express a corresponding weight value, thereby improving the accuracy of the storage and the accuracy of the data processing.

In another aspect of the present disclosure, the present disclosure also provides a data processing method based on a non-volatile memory array, as shown in FIG. 2, comprising:

Step S201, receiving a group of data values in the form of voltage input into the non-volatile memory array;

Step S202, processing the group of data values based on weight values stored in non-volatile memories of the non-volatile memory array, wherein a weight value in each of the non-volatile memories is stored according to any of the above described methods; and

Step S203 outputting a result of a multiply-accumulation operation performed on the group of data values and the weight values in the non-volatile memories.

The method provided in this embodiment can be applied to a neural network accelerator, which includes a non-volatile memory array for storing weight values and executing a multiply-accumulation operation. Of course, the methods provided in this embodiment can also be applied to other chips that require storing weight values and executing multiply-accumulation operations, which is not limited herein.

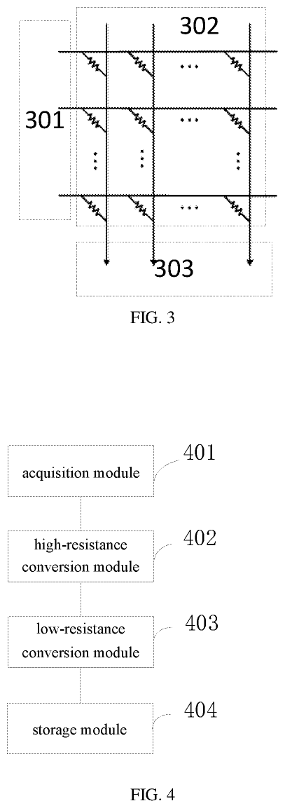

As the non-volatile memory array shown in FIG. 3, there is a weight value in each of the volatile memories, which is converted to be stored according to the storage method based on a non-volatile memory aforementioned in the present embodiment. The weight value can be preset, or be calculated according to a preset algorithm before the data processing is performed, which is not limited herein.

When it is required to process data, step S201 is first performed to receive a group of data values in the form of voltage input into the non-volatile memory array. The group of data values can be a data group of pixel values or a data group of amount values, which can be specifically set correspondingly according to different application fields of the neural network accelerator. Then, at step S202, the group of data values is processed based on the weight values stored in the non-volatile memories of the non-volatile memory array, i.e., performing a highly-parallel multiply-accumulation operation with the array of memories which converts weight values of a neural network to corresponding conductivity values based on the Kilhof current law. Then, Step S203 is performed to output a result of a multiply-accumulation operation performed on the group of data values and the weight values in the non-volatile memories. Specifically, as shown in FIG. 3, the electric current value output in an arrow direction of each column of columns is a result of the multiply-accumulation operation of the weight values corresponding to the memories in the each column and the group of data values, and the sum of the electric currents output by all the columns is a result of the multiply-accumulation operation of all the weight values of the non-volatile memory array and the group of data values.

With the non-volatile memory array of the present embodiment, it is determined whether a non-volatile memory in the array is a high-resistance memory device or a low-resistance memory device, and then different weight value-conductivity conversion methods are selected based on the type of the non-volatile memory, so that a converted conductivity value can represent a weight value more accurately, thereby increasing the accuracy of a multiply-accumulation operation.

In another aspect of the present disclosure, an embodiment of the present disclosure also provides a storage device based on a non-volatile memory, as shown in FIG. 4, comprising:

an acquisition module 401 configured for acquiring a weight value that needs to be stored in a non-volatile memory,

a high-resistance conversion module 402 configured for determining a conductivity value corresponding to a weight value according to the first conversion method if the non-volatile memory is a high-resistance storage device;

a low-resistance conversion module 403 configured for determining a conductivity value corresponding to a weight value according to the second conversion method which is different from the first conversion method if the non-volatile memory is a low-resistance memory device; and

a storage module 404 configured for setting the non-volatile memory according to the conductivity value to store the weight value.

Since the storage device described in the embodiment of the present disclosure is the device used by implementation of the storage method based on a non-volatile memory according to the embodiment of the present disclosure, a person skilled in the art could know the specific structure and various modifications thereof based on the method described in the embodiment of the present disclosure, which will not be described herein. All the devices implementing the method of the embodiment of the present disclosure belong to the scope of the present disclosure.

In another aspect of the present disclosure, an embodiment of the present disclosure also provides a non-volatile memory array, as shown in FIG. 3, comprising:

input ends 301 configured for receiving a group of data values in the form of voltage input into the non-volatile memory array;

an array module 302 configured for processing the group of data values based on weight values stored in non-volatile memories of the non-volatile memory array, wherein a weight value in each of the non-volatile memories is stored according to the storage method based on a non-volatile memory mentioned above in the present application; and

an output end 303 configured for outputting a result of a multiply-accumulation operation performed on the group of data values and the weight values in the non-volatile memories.

A non-volatile memory array provided in this embodiment can be integrated into a neural network accelerator for storing weight values and performing a multiply-accumulation operation. Of course, the non-volatile memory array provided in this embodiment can also be applied to other chips that require storing weight values and performing a multiply-accumulation operation, which are not limited herein.

In another aspect of the present disclosure, an embodiment of the present disclosure also provides a neural network accelerator, comprising the aforementioned non-volatile memory array provided in the present application.

In another aspect of the present disclosure, an embodiment of the present disclosure also provides an electronic apparatus comprising the aforementioned neural network accelerator provided in the present application.

Since the non-volatile memory array, the neural network accelerator, and the electronic apparatus described in the embodiments of the present disclosure, are hardware employed for implementing the method of the embodiment of the present disclosure, those skilled in the art could know the specific structure and various modifications of the hardware based on the method of the embodiment of the present disclosure, which are not described herein. All the hardware employed by the method of the embodiment of the present disclosure belongs to the scope of the present disclosure.

The technical solutions provided in the embodiments of the present disclosure have at least the following technical effects or advantages.

With the storage and data processing method, device, and apparatus based on a non-volatile memory according to the present disclosure, it is determined whether the non-volatile memory is a high-resistance memory device or a low-resistance memory device, and then different weight value-conductivity conversion methods are selected based on the type of the non-volatile memory, so that the converted conductivity value is more adaptable, and more accurately expresses the corresponding weight value, thereby increasing the accuracy of storage and the accuracy of data processing.

The algorithms and illustrations provided herein are not inherently associated with any particular computer, virtual system, or other apparatuses. Various general-purpose systems can also be used based on the teaching herein. According to the above description, the structure required to construct this type of system is apparent. In addition, the present disclosure is not directed to any specific programming language. It should be understood that the contents of the present disclosure described herein can be implemented by using various programming languages, and the description with respect to specific language above is just for the purpose of disclosing the preferred embodiments of the present disclosure.

In the specification provided here, a large number of specific details are explained. However, it will be appreciated that the embodiments of the present disclosure may be implemented without these specific details. In some examples, well-known methods, structures, and techniques are not shown in detail so that they will not obscure the understanding of the present specification.

Similarly, it should be understood that in order to simplify the present disclosure and help understand one or more aspects of the present disclosure, in the description of the exemplary embodiments of the present disclosure, the features of the present disclosure are sometimes grouped into a single embodiment, figure, or a description thereof. However, the method of the present disclosure should not be interpreted as reflecting the following intension: the invention to be protected in the present disclosure requires more features than the features specifically recited in each of the claims. More specifically, as reflected in the appended claims, the invention aspect includes features less than all features of a single embodiment disclosed above. Thus, the claims in conformity with specific embodiments are therefore expressly incorporated into the specific embodiments, and each of the claims itself serves as a single embodiment of the present disclosure.

Those skilled in the art should appreciate that the modules in an apparatus of an embodiment can be adaptively modified and they can be included in one or more apparatuses different from those of the embodiment. The modules or units or components in the embodiments can be combined into a module or unit or component, and they can also be divided into multiple sub-modules or sub-units or sub-components. Except that at least some of such features and/or processes or units are mutually exclusive, any combination can be made for all features, and all processes or units of any method or any apparatus disclosed in this specification (comprising the appended claims, abstracts, and drawings). Each of the features disclosed in this specification (comprising the appended claims, abstracts, and drawings) can be replaced by a substitute feature providing the same, equivalent or similar purpose.

Moreover, those skilled in the art will appreciate that although some embodiments herein include certain features included in other embodiments rather than other features, the combination of features in different embodiments falls within the scope of the present disclosure and forms a different embodiment. For example, in the claims, any of the claimed embodiments can be used in any combination.

Each of the components of the present disclosure may be implemented in hardware, or implemented in a software module running on one or more processors, or in their combination. Those skilled in the art will appreciate that some or all of the functionality of some or all of the components in the gateways, proxy servers, system according to the embodiments of the present disclosure can be implemented by a microprocessor or a distal signal processor (DSP). The present disclosure can also be implemented as an apparatus or device program (e.g., computer program, computer program product) for performing part or all of the methods described herein. Such programs for implementing the present disclosure can be stored on a computer readable medium or may have a form of one or more signals. Such signals can be downloaded from the Internet website or is provided on a carrier signal or provided in any other form.

It should be noted that the above-described embodiments are used to illustrate the present disclosure rather than limiting the present disclosure, and those skilled in the art can design substitute embodiments without departing from the scope of the appended claims. In the claims, any reference symbols in parentheses should not constitute any limitation to the claims. The words “comprise” or “include” or “contain” does not exclude components or steps not listed in the claims. The word “a” or “an” before a component does not exclude a plurality of such components. The present disclosure can be implemented by means of a hardware comprising several different components and a computer that is suitably programed. In a unit (device) type claim listing several units (devices), several units(devices) of these units(devises) may be embodied in a same hardware item. The use of words first, second, and third, etc. do not represent any order. These words can be interpreted as a name.

1. A storage method based on a non-volatile memory, comprising:
acquiring a weight value that needs to be stored in the non-volatile memory;
determining a conductivity value corresponding to the weight value according to a first conversion method, if the non-volatile memory is a high-resistance storage device;
determining a conductivity value corresponding to the weight value according to a second conversion method which is different from the first conversion method, if the non-volatile memory is a low-resistance memory device; and
setting the non-volatile memory according to the conductivity value to store the weight value.

2. The storage method according to claim 1, wherein the determining a conductivity value corresponding to the weight value according to a first conversion method comprising: determining a conductivity value corresponding to the weight value according to the following formula
$$G = \{ \begin{matrix}{g}_{min} , n = 0 \\ {g}_{min} * n * \frac{w}{{K}^{m} - 1} , n = 1 , . . . , {K}^{m} - 1\end{matrix} ,$$
where G is the conductivity value; n is the weight value, and gₘᵢₙ is a lowest conductivity value corresponding to a preset minimum weight value; K is a carry number of a carry system used for the weight value, and m is the number of digits of K carry system used for the weight value, and w is a conductivity switching ratio of the non-volatile memory.

3. The storage method according to claim 1, wherein the determining a conductivity value corresponding to the weight value according to a second conversion method comprising determining a conductivity value corresponding to the weight value according to the following formula
$$G = {g}_{min} + {g}_{min} * n * \frac{w - 1}{{K}^{m} - 1} , n = 0 , . . . , {K}^{m} - 1 ,$$
where G is the conductivity value; n is the weight value, and gₘᵢₙ is a lowest conductivity value corresponding to a preset minimum weight value; K is a carry number of a carry system used for the weight value, and m is the number of digits of K carry system used for the weight value, and w is a conductivity switching ratio of the non-volatile memory.

4. The storage method according to claim 1, wherein a carry system used for the weight value is a binary system.

5. The storage method according to claim 1, wherein the non-volatile memory is a non-volatile memory in a neural network accelerator, and the weight value is a weight value of a neural network.

6. A data processing method based on a non-volatile memory array, comprising:
receiving a group of data values in a form of voltage input into the non-volatile memory array;
processing the group of data values based on weight values stored in non-volatile memories of the non-volatile memory array; wherein the weight value in each of the non-volatile memories is stored according to a method based on a non-volatile memory; and
outputting a result of a multiply-accumulation operation performed on the group of data values and the weight values in the non-volatile memories;
the method based on a non-volatile memory, comprising:
acquiring a weight value that needs to be stored in the non-volatile memory;
determining a conductivity value corresponding to the weight value according to a first conversion method, if the non-volatile memory is a high-resistance storage device;
determining a conductivity value corresponding to the weight value according to a second conversion method which is different from the first conversion method, if the non-volatile memory is a low-resistance memory device; and
setting the non-volatile memory according to the conductivity value to store the weight value.

7. (canceled)

8. A non-volatile memory array comprising:
input ends configured for receiving a group of data values in a form of voltage input into the non-volatile memory array;
an array module configured for processing the group of data values based on weight values stored in non-volatile memories of the non-volatile memory array, wherein a weight value in each of the non-volatile memories is stored according to a method based on a non-volatile memory; and
an output end configured for outputting a result of a multiply-accumulation operation performed on the group of data values and the weight values in the non-volatile memories;
the method based on a non-volatile memory, comprising:
acquiring a weight value that needs to be stored in the non-volatile memory;
determining a conductivity value corresponding to the weight value according to a first conversion method, if the non-volatile memory is a high-resistance storage device;
determining a conductivity value corresponding to the weight value according to a second conversion method which is different from the first conversion method, if the non-volatile memory is a low-resistance memory device; and
setting the non-volatile memory according to the conductivity value to store the weight value.

9. (canceled)

10. (canceled)

11. The data processing method according to claim 6, wherein the determining a conductivity value corresponding to the weight value according to a first conversion method comprising: determining a conductivity value corresponding to the weight value according to the following formula
$$G = \{ \begin{matrix}{g}_{min} , n = 0 \\ {g}_{min} * n * \frac{w}{{K}^{m} - 1} , n = 1 , . . . , {K}^{m} - 1\end{matrix} ,$$
where G is the conductivity value; n is the weight value, and gₘᵢₙ is a lowest conductivity value corresponding to a preset minimum weight value; K is a carry number of a carry system used for the weight value, and m is the number of digits of K carry system used for the weight value, and w is a conductivity switching ratio of the non-volatile memory.

12. The data processing method according to claim 6, wherein the determining a conductivity value corresponding to the weight value according to a second conversion method comprising: determining a conductivity value corresponding to the weight value according to the following formula
$$G = {g}_{min} + {g}_{min} * n * \frac{w - 1}{{K}^{m} - 1} , n = 0 , . . . , {K}^{m} - 1 ,$$
where G is the conductivity value; n is the weight value, and gₘᵢₙ is a lowest conductivity value corresponding to a preset minimum weight value; K is a carry number of a carry system used for the weight value, and m is the number of digits of K carry system used for the weight value, and w is a conductivity switching ratio of the non-volatile memory.

13. The non-volatile memory array according to claim 8, wherein the determining a conductivity value corresponding to the weight value according to a first conversion method comprising: determining a conductivity value corresponding to the weight value according to the following formula
$$G = \{ \begin{matrix}{g}_{min} , n = 0 \\ {g}_{min} * n * \frac{w}{{K}^{m} - 1} , n = 1 , . . . , {K}^{m} - 1\end{matrix} ,$$
where G is the conductivity value; n is the weight value, and gₘᵢₙ is a lowest conductivity value corresponding to a preset minimum weight value; K is a carry number of a carry system used for the weight value, and m is the number of digits of K carry system used for the weight value, and w is a conductivity switching ratio of the non-volatile memory.

14. The non-volatile memory array according to claim 8, wherein the determining a conductivity value corresponding to the weight value according to a second conversion method comprising: determining a conductivity value corresponding to the weight value according to the following formula
$$G = {g}_{min} + {g}_{min} * n * \frac{w - 1}{{K}^{m} - 1} , n = 0 , . . . , {K}^{m} - 1 ,$$
where G is the conductivity value; n is the weight value, and gₘᵢₙ is a lowest conductivity value corresponding to a preset minimum weight value; K is a carry number of a carry system used for the weight value, and m is the number of digits of K carry system used for the weight value, and w is a conductivity switching ratio of the non-volatile memory.
